(19) United States
(12) Patent Application Publication
(10) Pub. No.: US 2025/0207244 A1
(43) Pub. Date: Jun. 26, 2025

(54) FILM FORMATION METHOD AND FILM FORMATION DEVICE

(71) Applicant: Tokyo Electron Limited, Minato-ku, Tokyo (JP)

(72) Inventors: Shuji AZUMO, Nirasaki City, Yamanashi (JP); Yumiko KAWANO, Nirasaki City, Yamanashi (JP); Shinichi IKE, Hwaseong-si, Gyeonggi-do (KR)

(21) Appl. No.: 18/848,660

(22) PCT Filed: Mar. 14, 2023
(86) PCT No.: PCT/JP2023/009847

§ 371 Date: Sep. 19, 2024

(30) Foreign Application Priority Data
Mar. 25, 2022 (JP) 2022-049569

(51) Int. Cl. C23C 16/04; C23C 16/455; C23C 16/52; C23C 16/56; H01L 21/311

(52) U.S. Cl. CPC C23C 16/042; C23C 16/45525; C23C 16/52; C23C 16/56; H01L 21/31116

(57) ABSTRACT

A film forming method includes (A) to (E) below. (A) A substrate having a first film and a second film in different regions of a surface of the substrate is prepared. (B) A self-assembled monolayer is selectively formed on a surface of the second film using an organic compound not containing fluorine. (C) After (B), a target film is formed on a surface of the first film while inhibiting the target film from being formed on the surface of the second film using the self-assembled monolayer. (D) After (C), a partial portion of the target film is fluorinated faster than a remaining portion of the target film using a fluorine-containing gas. (E) After (D), the partial portion of the target film is etched faster than the remaining portion of the target film using an etching gas. The partial portion of the target film is deposited on the self-assembled monolayer.

### TECHNICAL FIELD

The present disclosure relates to a film forming method and a film forming apparatus.

### BACKGROUND

Patent Document 1 discloses a film forming method in which while inhibiting a target film (third film) from being formed on a portion of a substrate surface by using a self-assembled monolayer (SAM), the target film (third film) is formed on another portion of the substrate surface. In Patent Document 1, an organic compound containing fluorine is used as a precursor of the SAM. After the target film is formed, the SAM is excited by irradiating the target film with at least any ones of ions and active species to generate active species containing fluorine and carbon. Then, the active species containing fluorine and carbon react with a side portion of the target film adjacent to the SAM. As a result, the side portion of the target film becomes a volatile compound and is removed.

### PRIOR ART DOCUMENT

### Patent Document

Patent Document 1: Japanese patent laid-open publication No. 2021-44534

One aspect of the present disclosure provides a technique in which an organic compound not containing fluorine is used as a precursor of a SAM and a portion of a target film deposited on a SAM is selectively removed.

### SUMMARY

According to one embodiment of the present disclosure, there is provided a film forming method including (A) to (E) below. (A) A substrate having a first film and a second film made of a material different from a material of the first film in different regions of a surface of the substrate is prepared. (B) A self-assembled monolayer is selectively formed on a surface of the second film with respect to a surface of the first film using an organic compound not containing fluorine. (C) After (B), a target film is formed on the surface of the first film while inhibiting the target film from being formed on the surface of the second film using the self-assembled monolayer. (D) After (C), a partial portion of the target film is fluorinated faster than a remaining portion of the target film using a fluorine-containing gas. (E) After (D), the partial portion of the target film is etched faster than the remaining portion of the target film using an etching gas. The partial portion of the target film is deposited on the self-assembled monolayer.

According to one aspect of the present disclosure, an organic compound not containing fluorine is used as a precursor of a SAM and a portion of a target film deposited on a SAM can be selectively removed.

### BRIEF DESCRIPTION OF DRAWINGS

FIG. 1 is a flowchart illustrating a film forming method according to an embodiment.

FIG. 2A is a diagram illustrating a first example of step S101.

FIG. 2B is a diagram illustrating a first example of step S102.

FIG. 2C is a diagram illustrating a first example of step S103.

FIG. 2D is a diagram illustrating a first example of step S104.

FIG. 2E is a diagram illustrating a first example of step S105.

FIG. 2F is a diagram illustrating a first example as a result of repeating steps S106 and S107.

FIG. 3A is a diagram illustrating a first example of step S106.

FIG. 3B is a diagram illustrating a first example of step S107.

FIG. 4 is a flowchart illustrating a modified example of FIG. 1.

FIG. 5A is a diagram illustrating a second example of step S101.

FIG. 5B is a diagram illustrating a second example of step S102.

FIG. 5C is a diagram illustrating a second example of step S103.

FIG. 5D is a diagram illustrating a second example of step S104.

FIG. 5E is a diagram illustrating a second example of step S105.

FIG. 5F is a diagram illustrating a second example as a result of repeating steps S106 and S107.

FIG. 6A is a diagram illustrating a third example of step S101.

FIG. 6B is a diagram illustrating a third example of step S102.

FIG. 6C is a diagram illustrating a third example of step S103.

FIG. 6D is a diagram illustrating a third example of step S104.

FIG. 6E is a diagram illustrating a third example of step S105.

FIG. 6F is a diagram illustrating a third example as a result of repeating steps S106 and S107.

FIG. 7 is a plan view illustrating a film forming apparatus according to an embodiment.

FIG. 8 is a cross-sectional view illustrating an example of a first processor in FIG. 7.

### DETAILED DESCRIPTION

Hereinafter, embodiments of the present disclosure will be described with reference to the accompanying drawings. In each drawing, the same or corresponding components are denoted by the same reference numerals, and the description thereof may be omitted.

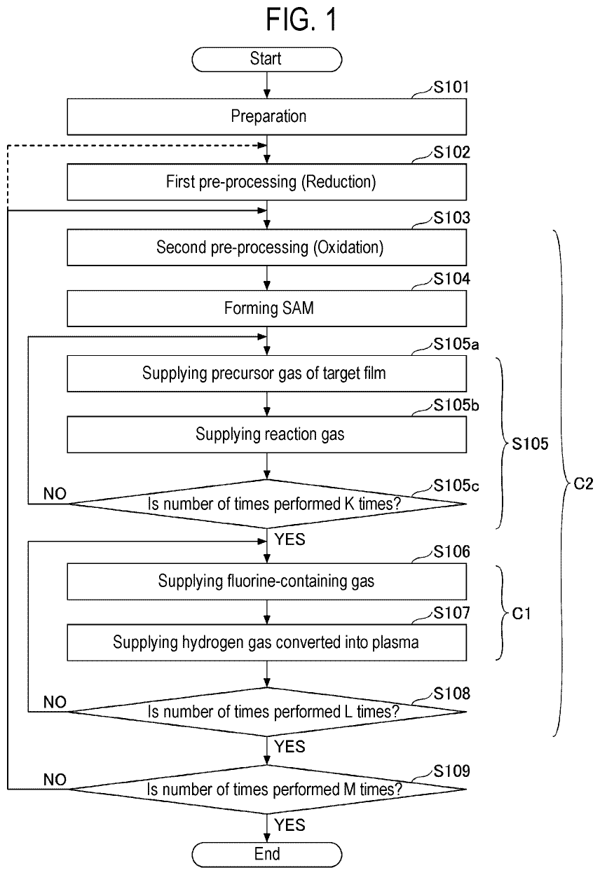

A film forming method according to an embodiment will now be described with reference to FIGS. 1 to 3B. The film forming method includes, for example, steps S101 to S109 illustrated in FIG. 1. The film forming method may include at least step S101 and steps S104 to S107. The film forming method may not include, for example, steps S102 and S103. The film forming method may include another steps in addition to steps S101 to S109 illustrated in FIG. 1.

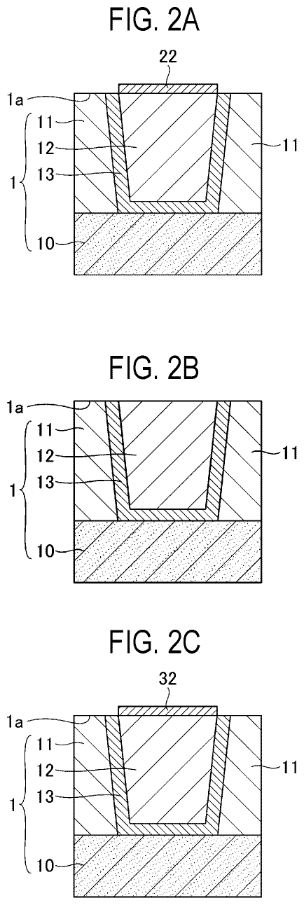

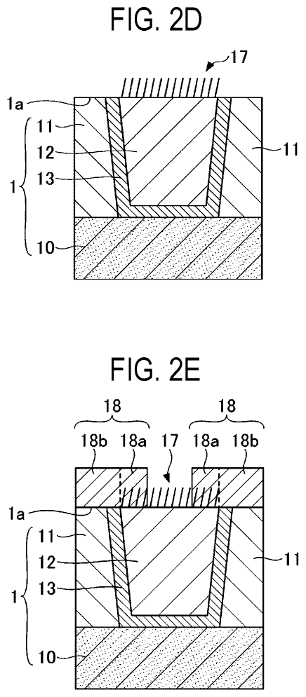

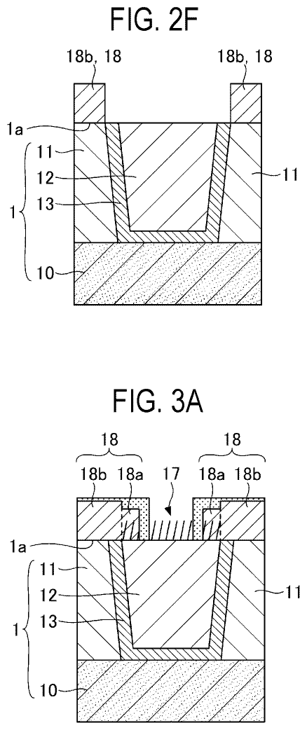

Step S101 in FIG. 1 includes preparing a substrate 1 as illustrated in FIG. 2A. The substrate 1 has a base substrate 10. The base substrate 10 is, for example, a silicon wafer, a compound semiconductor wafer, or a glass substrate. The substrate 1 has an insulating film 11 and a conductive film 12 in different regions of a substrate surface 1a. The substrate surface 1a is, for example, an upper surface of the substrate 1. The insulating film 11 and the conductive film 12 are formed on the base substrate 10. Another functional film may be formed between the base substrate 10 and the insulating film 11 or between the base substrate 10 and the conductive film 12. The insulating film 11 is an example of a first film, and the conductive film 12 is an example of a second film. The materials of the first film and the second film are not particularly limited. The first film may be a conductive film, and the second film may be an insulating film.

The insulating film 11 is, for example, an interlayer insulating film. The interlayer insulating film is desirably a low dielectric constant (low-k) film. The insulating film 11 is, without being particularly limited to for example, a SiO film, a SiN film, a SiC film, a SiOC film, a SiCN film, a SiON film, or a SiOCN film. Here, the SiO film means a film containing silicon (Si) and oxygen (O). The atomic ratio of Si to O in the SiO film is usually 1:2 but is not limited to 1:2. Similarly, each of the SiN film, the SiC film, the SiOC film, the SiCN film, the SiON film, and the SiOCN film also means a film containing corresponding elements and is not limited to a stoichiometric ratio. The insulating film 11 has a recess on the substrate surface 1a. The recess is a trench, a contact hole, or a via hole.

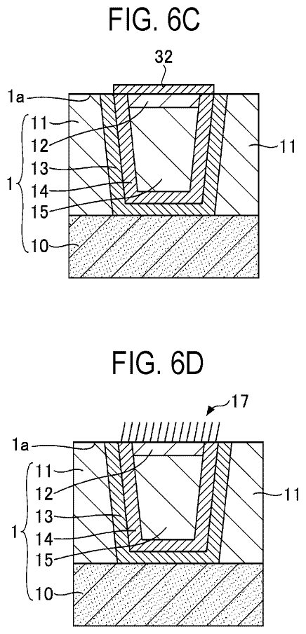

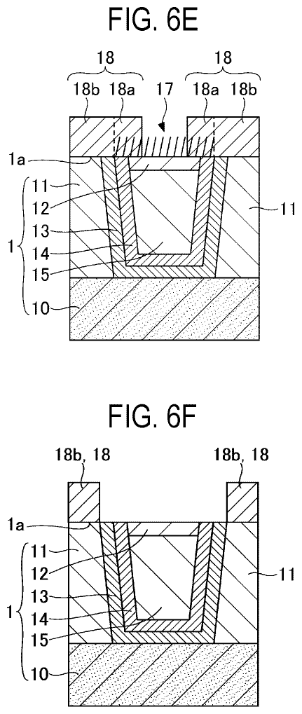

The conductive film 12 is filled, for example, in the recess of the insulating film 11. The conductive film 12 is, for example, a metal film. The metal film is, for example, a Cu film, a Co film, a Ru film, a W film, or a Mo film. The conductive film 12 may be a cap film. In other words, as illustrated in FIG. 6A, a second conductive film 15 may be embedded in the recess of the insulating film 11, and the second conductive film 15 may be covered by the conductive film 12. The second conductive film 15 is formed of a metal different from that of the conductive film 12.

The substrate 1 may further have a third film on the substrate surface 1a. The third film is, for example, a barrier film 13. The barrier film 13 is formed between the insulating film 11 and the conductive film 12 and suppresses metal diffusion from the conductive film 12 to the insulating film 11. The barrier film 13 is, without being limited to, for example, a TaN film or a TiN film. Here, the TaN film means a film containing tantalum (Ta) and nitrogen (N). The atomic ratio of Ta to N in the TaN film is usually 1:1 but is not limited to 1:1. Similarly, the TiN film means a film containing corresponding elements and is not limited to a stoichiometric ratio.

Table 1 summarizes specific examples of the insulating film 11, the conductive film 12, and the barrier film 13.

TABLE 1

| Insulating Film | Conductive Film | Barrier Film |
|---|---|---|
| SiO Film | Cu Film | TaN Film |
| SiN Film | Co Film | TiN Film |
| SiOC Film | Ru Film | |
| SiON Film | W Film | |
| SiOCN Film | | |
| SiCN Film | | |

A combination of the insulating film 11, the conductive film 12, and the barrier film 13 is not particularly limited.

Step S102 in FIG. 1 includes cleaning the substrate surface 1a as illustrated in FIG. 2B. A contaminant 22 (see FIG. 2A) present on the substrate surface 1a can be removed. The contaminant 22 includes, for example, at least one of a metal oxide and an organic material. The metal oxide is an oxide formed by a reaction between the conductive film 12 and the atmosphere and is a so-called natural oxide film. The organic material is, for example, a deposit containing carbon and adheres to the substrate 1 during a processing process.

For example, step S102 includes supplying a cleaning gas to the substrate surface 1a. The cleaning gas may be converted into plasma in order to improve the removal efficiency of the contaminant 22. The cleaning gas includes, for example, a reducing gas such as H₂ gas. The reducing gas removes the contaminant 22. Step S102 is a dry process but may also be a wet process.

An example of processing conditions for step S102 is as follows.
Flow rate of H₂ gas: 200 sccm to 3,000 sccm
Power supply frequency for plasma generation: 400 kHz to 40 MHz
Power for plasma generation: 50 W to 1,000 W
Processing time: 1 second to 60 seconds
Processing temperature: 50 degrees C. to 300 degrees C.

Processing pressure: 10 Pa to 7,000 Pa

Step S103 in FIG. 1 includes forming an oxide film 32 by oxidizing the surface of the conductive film 12 as illustrated in FIG. 2C. For example, step S103 includes forming the oxide film 32 by supplying an oxygen-containing gas to the substrate surface 1a. The oxygen-containing gas includes at least one selected from among O₂ gas, O₃ gas, H₂O gas, NO gas, NO₂ gas, and N₂O gas. Step S103 is a dry process but may be a wet process.

Because the contaminant 22 has been removed before step S103, the oxide film 32 having a desired film thickness and desired film quality is obtained by step S103. The film quality includes the surface state of a film. Unlike the natural oxide film, the film thickness and film quality of the oxide film 32 can be controlled according to a raw material gas and film formation conditions. By forming the oxide film 32 having a desired film thickness and desired film quality, a dense self-assembled monolayer (SAM) can be formed on the surface of the conductive film 12 in step S104 described later.

An example of processing conditions for step S103 is as follows.
Flow rate of O₂ gas: 100 sccm to 2,000 sccm
Processing time: 10 seconds to 300 seconds
Processing temperature: 100 degrees C. to 250 degrees C.
Processing pressure: 200 Pa to 1,200 Pa

Step S104 in FIG. 1 includes selectively forming a SAM 17 on the surface of the conductive film 12 with respect to the surface of the insulating film 11 using an organic compound not containing fluorine, as illustrated in FIG. 2D. The SAM 17 is formed by supplying a gas of the organic compound into a processing container that accommodates the substrate 1. The organic compound is a precursor of the SAM 17.

The use of the organic compound not containing fluorine as the precursor of the SAM 17 contributes to environmental conservation. Compared with an organic compound that contains fluorine, the organic compound not containing fluorine hardly remains in the processing container accommodating the substrate 1, so that the stability (reproducibility) of the processing quality of the substrate 1 can be raised.

The organic compound includes, for example, a first functional group, and a second functional group provided at one end of the first functional group. The first functional group is, for example, a hydrocarbon group. The first functional group is desirably linear. The first functional group is desirably an alkyl group. The first functional group may have an unsaturated bond such as a double bond. The second functional group is chemically adsorbed to the surface of the conductive film 12.

The organic compound as the precursor of the SAM 17 is not particularly limited but may be, for example, a thiol-based compound. The thiol-based compound is represented by a general formula “R—SH”. R is, for example, a hydrocarbon group and corresponds to the first functional group. The SH group corresponds to the second functional group. A specific example of the thiol-based compound is CH₃(CH₂)ₓCH₂SH (where X is an integer of 1 to 16).

The thiol-based compound is more likely to be chemically adsorbed to the surface of the conductive film 12 than to the surface of the insulating film 11. Therefore, the SAM 17 is selectively formed on the surface of the conductive film 12 with respect to the surface of the insulating film 11. The SAM 17 is not formed on the surface of the insulating film 11 and is hardly formed on the surface of the barrier film 13.

When the oxide film 32 is formed before the SAM 17 is formed, the density of the SAM 17 can be improved compared to the case in which the oxide film 32 is not formed, and the blocking performance of the SAM 17 can be improved in step S105 described later. Since the thiol-based compound is chemically adsorbed to the oxide film 32 while reducing the oxide film 32, the oxide film 32 does not necessarily have to remain after step S104 (see FIGS. 2D, 5D, and 6D).

The precursor of the SAM 17 is not limited to the thiol-based compound. For example, the precursor of the SAM 17 may be an organic silane-based compound, a phosphonic acid-based compound, or an isocyanate-based compound. The organic silane-based compound is represented by a general formula “R—Si(OCH₃)₃” or “R—SiCl₃”. The phosphonic acid-based compound is represented by a general formula “R—P(═O)(OH)₂”. The isocyanate-based compound is represented by a general formula “R—N═C═O”. In these general formulas, R is, for example, a hydrocarbon group.

An example of processing conditions for step S104 is as follows.
Flow rate of gas of organic compound: 50 sccm to 500 sccm
Processing time: 10 seconds to 1,800 seconds
Processing temperature: 100 degrees C. to 350 degrees C.
Processing pressure: 100 Pa to 14,000 Pa

Step S105 in FIG. 1 includes forming a target film 18 on the surface of the insulating film 11 while inhibiting the target film 18 from being formed on the surface of the conductive film 12 using the SAM 17, as illustrated in FIG. 2E. The target film 18 is, for example, an insulating film. The target film 18 is not particularly limited but may be, for example, an AlO film, a SiO film, a SiN film, a ZrO film, or a HfO film. Here, the AlO film means a film containing aluminum (Al) and oxygen (O). The atomic ratio of Al to O in the AlO film is usually 2:3 but is not limited to 2:3. Similarly, each of the SiO film, SiN film, ZrO film, and HfO film also means a film containing corresponding elements and is not limited to a stoichiometric ratio.

The target film 18 is formed, for example, by an atomic layer deposition (ALD) method. When the target film 18 is formed by the ALD method, a precursor gas of the target film 18 and a reaction gas are alternately supplied to the substrate surface 1a. The precursor gas of the target film 18 contains, for example, a metal element or a metalloid element.

The reaction gas forms the target film 18 by reacting with the precursor gas of the target film 18. The reaction gas is, for example, an oxidizing gas or a nitriding gas. The oxidizing gas forms an oxide film of a metal element or a metalloid element contained in the precursor gas. The nitriding gas forms a nitride film of the metal element or the metalloid element contained in the precursor gas.

In addition, the reaction gas may be a reducing gas. The reducing gas forms a metal film or a semiconductor film using the metal element or the metalloid element contained in the precursor gas. The target film 18 may be the metal film or the semiconductor film.

Further, the target film 18 may be formed by a chemical vapor deposition (CVD) method. When the target film 18 is formed by the CVD method, the precursor gas of the target film 18 and the reaction gas are simultaneously supplied to the substrate surface 1a.

Hereinafter, the case in which the target film 18 is formed by the ALD method will be described. Step S105 includes steps S105a to S105c, as illustrated in FIG. 1. The order of steps S105a and S105b may be reversed. In addition, between steps S105a and S105b, there may be a step of discharging various gases remaining in the processing container by supplying an inert gas such as argon gas into the processing container.

Step S105a includes supplying the precursor gas of the target film 18 to the substrate surface 1a. Since the SAM 17 has been formed on the surface of the conductive film 12, the precursor gas is selectively adsorbed to the surface of the insulating film 11. An example of processing conditions for step S105a is shown below. In the processing conditions below, trimethylaluminum (TMA) gas is a precursor gas of an AlO film.
Flow rate of TMA gas: 1 sccm to 300 sccm (desirably 50 sccm)
Processing time: 0.1 to 2 seconds
Processing temperature: 100 degrees C. to 250 degrees C.
Processing pressure: 133 Pa to 1,200 Pa

Step S105b includes supplying a reaction gas to the substrate surface 1a. The reaction gas forms the target film 18 by reacting with the precursor gas of the target film 18. An example of processing conditions for step S105b is shown below. In the processing conditions below, H₂O gas forms the AlO film by reacting with the TMA gas.
Flow rate of H₂O gas: 10 sccm to 200 sccm
Processing time: 0.1 seconds to 2 seconds
Processing temperature: 100 degrees C. to 250 degrees C.
Processing pressure: 133 Pa to 1,200 Pa

Step S105c includes checking whether steps S105a and S105b have been performed a set number of times (K times). The set number of times (K times) is determined according to a target film thickness of the target film 18 and is, for example, 20 to 80 times.

If the number of times performed has not reached the set number (K times) (“NO” in step S105c), the thickness of the target film 18 has not reached the target thickness, so steps S105a and S105b are performed again. On the other hand, if the number of times performed has reached the set number (K times) (“YES” in step S105c), the thickness of the target film 18 has reached the target thickness, so the processing of step S106 and subsequent steps is performed.

However, as illustrated in FIG. 2E, while the SAM 17 inhibits the target film 18 from being formed, the blocking performance of the SAM 17 is not perfect. Therefore, the target film 18 protrudes horizontally from the surface of the insulating film 11. A partial portion 18a of the target film 18 is deposited on the SAM 17. If the partial portion 18a of the target film 18 covers the surface of the conductive film 12, the wiring resistance of the substrate 1 increases, so the partial portion 18a of the target film 18 is removed from the surface of the conductive film 12, as will be described later.

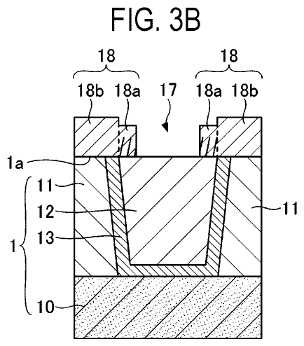

Step S106 in FIG. 1 includes, as illustrated in FIG. 3A, fluorinating the partial portion 18a of the target film 18 faster than a remaining portion 18b of the target film 18, using a fluorine-containing gas. In FIG. 3A, a fluorinated portion of the target film 18 is represented by a dot pattern. The partial portion 18a of the target film 18 is not only deeply fluorinated from a top surface downward, compared to the remaining portion 18b of the target film 18, but also fluorinated from even a side surface, unlike the remaining portion 18b of the target film 18.

The partial portion 18a of the target film 18 is deposited on the SAM 17 and contains an organic compound. Therefore, the partial portion 18a of the target film 18 is more likely to be fluorinated than the remaining portion 18b of the target film 18. The fluorine-containing gas is not particularly limited as long as the fluorine-containing gas contains fluorine but includes, for example, at least one selected from among HF gas, F₂ gas, and ClF₃ gas.

An example of processing conditions for step S106 is shown below.
Flow rate of fluorine-containing gas: 50 sccm to 500 sccm
Processing time: 1 second to 120 seconds
Processing temperature: 100 degrees C. to 400 degrees C.
Processing pressure: 1.333 Pa to 1,200 Pa

Step S107 in FIG. 1 includes, as illustrated in FIG. 3B, etching the partial portion 18a of the target film 18 faster than the remaining portion 18b of the target film 18 using an etching gas.

The etching gas is not particularly limited but includes, for example, at least one selected from among H₂ gas, NH₃ gas, N₂ gas, and Ar gas and may be a mixed gas thereof (e.g., a mixed gas of H₂ gas and Ar gas). The etching gas is supplied to the substrate surface 1a in a plasma state.

H₂ gas, NH₃ gas, N₂ gas, or Ar gas, or a mixed gas thereof which is converted into plasma activates the fluorinated portion of the target film 18, so the fluorinated portion of the target film 18 is changed into a volatile compound. Thereby, the fluorinated portion of the target film 18 is etched. An etching rate depends on the progress of fluorination and is faster as the fluorination progresses.

Since the partial portion 18a of the target film 18 has been more fluorinated than the remaining portion 18b of the target film 18, the etching rate is faster in the partial portion 18a of the target film 18. Thereby, while the partial portion 18a of the target film 18 is removed from above the conductive film 12, the remaining portion 18b of the target film 18 remains on the insulating film 11.

An example of processing conditions for step S107 is shown below.
Flow rate of H₂ gas: 200 sccm to 3,000 sccm
Power supply frequency for plasma generation: 400 kHz to 40 MHz
Power for plasma generation: 50 W to 1,000 W
Processing time: 1 second to 60 seconds
Processing temperature: 50 degrees C. to 300 degrees C.
Processing pressure: 10 Pa to 7,000 Pa

Step S108 includes checking whether a first cycle C1 has been performed a set number of times (L times). The first cycle C1 includes steps S106 and S107. The set number of times (L times) only needs to be set such that the partial portion 18a of the target film 18 can be removed. The set number of times (L times) may be once but is desirably multiple times. By repeatedly performing the first cycle C1 multiple times, etching amount can be increased. The set number of times (L times) is, for example, 1 to 50.

If the number of times of performing the first cycle C1 has not reached the set number of times (L times) (“NO” in step S108), the partial portion 18a of the target film 18 has not been removed, so the first cycle C1 is performed again. On the other hand, if the number of times of performing the first cycle C1 has reached the set number of times (L times) (“YES” in step S108), the partial portion 18a of the target film 18 has been removed, so processing of step S109 and subsequent steps are performed.

Step S109 includes checking whether a second cycle C2 has been performed a set number of times (M times). The second cycle C2 includes at least steps S104 to S107. In each second cycle C2, the first cycle C1 is performed L times after steps S104 and S105 are performed. When L is an integer equal to or greater than 2, the first cycle C1 is repeated in each second cycle C2.

The second cycle C2 may also include step S103. If the SAM 17 remains on the surface of the conductive film 12 after step S107, the second cycle C2 may also include step S102. The H₂ gas or the like which is converted into plasma, used in step S102, removes the SAM 17 by decomposing the SAM 17.

The set number of times (M times) in step S109 is set so that the film thickness of the target film 18 remaining on the surface of the insulating film 11 becomes a second target film thickness. The second target film thickness may be the same as a target film thickness corresponding to the set number of times (K times) in step S105c or may be greater than the target film thickness. The set number of times (M times) in step S109 is, for example, 1 to 10.

When the number of performing the second cycle C2 has not reached the set number (M times) (“NO” in step S109), the film thickness of the target film 18 remaining on the surface of the insulating film 11 has not reached the second target film thickness, so the second cycle C2 is performed again. On the other hand, when the number of times of performing the second cycle C2 has reached the set number of times (M times) (“YES” in step S109), the film thickness of the target film 18 remaining on the surface of the insulating film 11 has reached the second target film thickness, so current processing is ended.

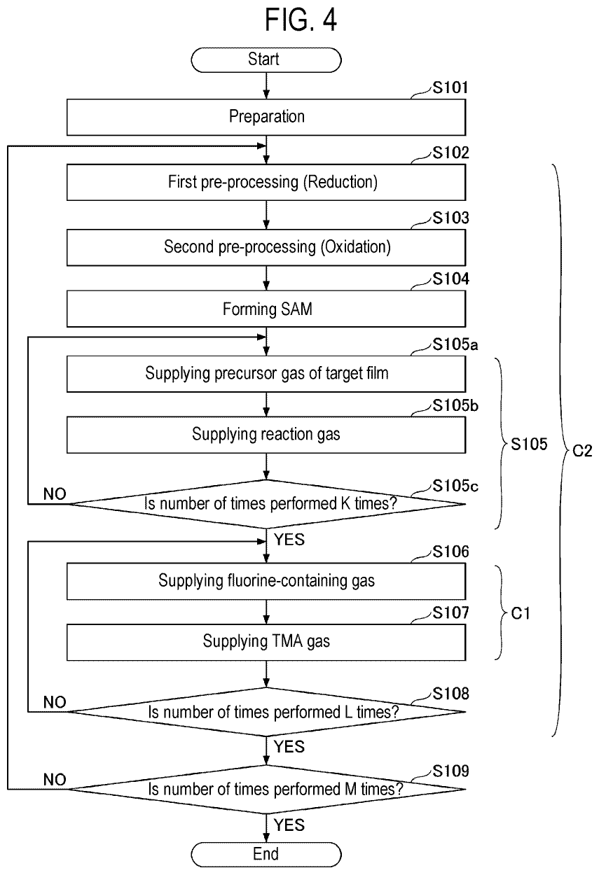

Next, a modified example of FIG. 1 will be described with reference to FIG. 4. Hereinbelow, differences will be described. In step S107 of the modified example, the etching gas includes at least one selected from among trimethylaluminum (TMA) gas, dimethylacetamide (DMAC) gas, tin (II) acetylacetonate gas, Cl₂ gas, BCl₃ gas, and TiCl₄ gas.

The TMA gas, DMAC gas, tin (II) acetylacetonate gas, Cl₂ gas, BCl₃ gas, or TiCl₄ gas changes the fluorinated portion of the target film 18 into a volatile compound by a ligand exchange reaction. Thereby, the fluorinated portion of the target film 18 is etched. An etching rate depends on the progress of fluorination and is faster as the fluorination progresses.

Since the partial portion 18a of the target film 18 has been more fluorinated than the remaining portion 18b of the target film 18, the etching rate is faster in the partial portion 18a of the target film 18. Thereby, while the partial portion 18a of the target film 18 is removed from above the conductive film 12, the remaining portion 18b of the target film 18 remains on the insulating film 11.

An example of processing conditions for step S107 is shown below.
Flow rate of etching gas: 10 sccm to 500 sccm
Processing time: 1 second to 30 seconds
Processing temperature: 100 degrees C. to 400 degrees C.
Processing pressure: 10 Pa to 1,500 Pa

Unlike H₂ gas which is converted into plasma, TMA gas, DMAC gas, tin (II) acetylacetonate gas, Cl₂ gas, BCl₃ gas, or TiCl₄ gas used in step S107 does not decompose the SAM 17. Therefore, the second cycle C2 includes step S102. The H₂ gas or the like which is converted into plasma, used in step S102, removes the SAM 17 by decomposing the SAM 17.

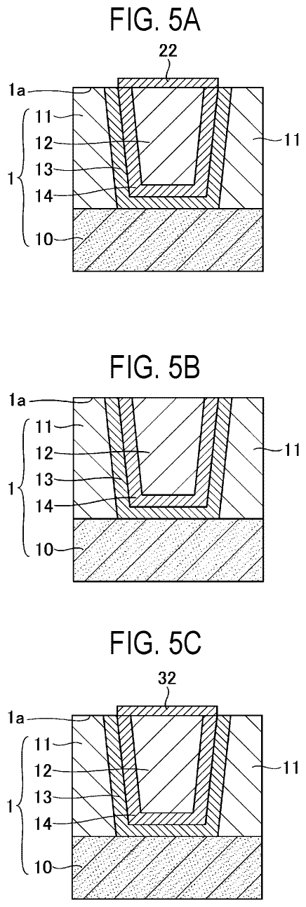

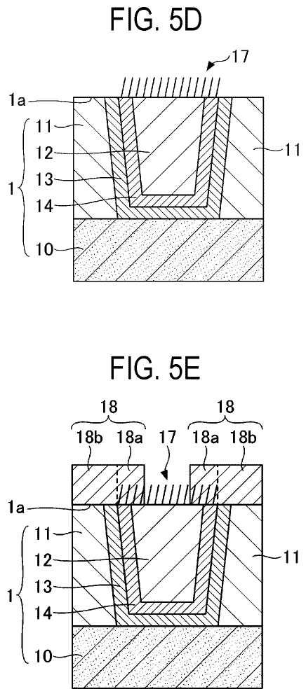

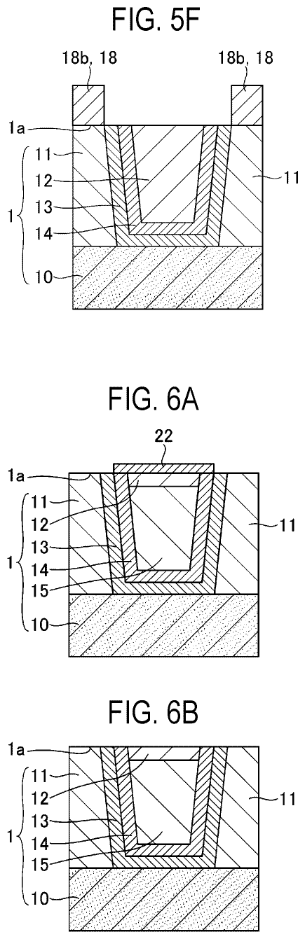

Next, the case in which the substrate 1 according to a first modified example is processed by the method of FIG. 1 will be described with reference to FIGS. 5A to 5F. The substrate 1 illustrated in FIG. 5A may be processed by the method of FIG. 4. Hereinbelow, differences will mainly be described.

As illustrated in FIG. 5A, the substrate 1 has a liner film 14, in addition to the insulating film 11, the conductive film 12, and the barrier film 13, on the substrate surface 1a. The liner film 14 is formed between the conductive film 12 and the barrier film 13. The liner film 14 is formed on the barrier film 13 and assists in the formation of the conductive film 12. The conductive film 12 is formed on the liner film 14. The liner film 14 is not particularly limited but is, for example, a Co film or a Ru film.

Table 2 summarizes a specific example of the insulating film 11, the conductive film 12, the barrier film 13, and the liner film 14.

TABLE 2

| Insulating Film | Conductive Film | Barrier Film | Liner Film |
|---|---|---|---|
| SiO Film | Cu Film | TaN Film | Co Film |
| SiN Film | | TiN Film | Ru Film |
| SiOC Film | | | |
| SiON Film | | | |
| SiOCN Film | | | |
| SiCN Film | | | |

A combination of the insulating film 11, the conductive film 12, the barrier film 13, and the liner film 14 is not particularly limited.

Step S102 according to the modified example includes removing the contaminant 22 (see FIG. 5A) as illustrated in FIG. 5B. The contaminant 22 is present, for example, on the surface of the conductive film 12 and the surface of the liner film 14. The surface of the conductive film 12 and the surface of the liner film 14 are exposed by step S102.

Step S103 according to the modified example includes forming the oxide film 32 by oxidizing the surface of the conductive film 12 and the surface of the liner film 14, as illustrated in FIG. 5C. Thereby, the dense SAM 17 can be formed on the surface of the conductive film 12 and the surface of the liner film 14 in step S104 described below.

Step S104 according to the modified example includes selectively forming the SAM 17 on the surface of the conductive film 12 and the surface of the liner film 14 with respect to the surface of the insulating film 11, as illustrated in FIG. 5D. The SAM 17 is not formed on the surface of the insulating film 11 and is hardly formed on the surface of the barrier film 13.

Step S105 according to the modified example includes forming the target film 18 on the surface of the insulating film 11 while inhibiting the target film 18 from being formed on the surface of the conductive film 12 and the surface of the liner film 14 using the SAM 17, as illustrated in FIG. 5E.

As illustrated in FIG. 5E, while the SAM 17 inhibits the target film 18 from being formed, the blocking performance of the SAM 17 is not perfect. Therefore, the target film 18 protrudes horizontally from the surface of the insulating film 11. The partial portion 18a of the target film 18 is deposited on the SAM 17.

Even in the modified example, the partial portion 18a of the target film 18 can be removed by performing steps S106 and S107, as illustrated in FIG. 5F, as in the embodiment. While the partial portion 18a of the target film 18 is removed from the conductive film 12, the remaining portion 18b of the target film 18 remains on the insulating film 11.

Next, the case in which the substrate 1 according to a second modified example is processed by the method of FIG. 1 will be described with reference to FIGS. 6A to 6F. The substrate 1 illustrated in FIG. 6A may be processed by the method of FIG. 4. Hereinbelow, differences will mainly be described.

As illustrated in FIG. 6A, the conductive film 12 of the substrate 1 may be a cap film. That is, as illustrated in FIG. 6A, the second conductive film 15 may be filled in the recess of the insulating film 11, and the conductive film 12 may cover the second conductive film 15. The second conductive film 15 is formed of a metal different from that of the conductive film 12.

Table 3 summarizes a specific example of the conductive film (cap film) 12, the barrier film 13, the liner film 14, and the second conductive film 15.

TABLE 3

| | Conductive | | | Second |
|---|---|---|---|---|
| | Film (Cap | | | Conductive |
| Insulating Film | Film) | Barrier Film | Liner Film | Film |
| SiO Film | Co Film | TaN Film | Co Film | Cu Film |
| SiN Film | Ru Film | TiN Film | Ru Film | |
| SiOC Film | | | | |
| SiON Film | | | | |
| SiOCN Film | | | | |
| SiCN Film | | | | |

A combination of the insulating film 11, the conductive film 12, the barrier film 13, the liner film 14, and the second conductive film 15 is not particularly limited.

Steps S102 to S107 according to the second modified example (see FIGS. 6B to 6F) are performed in the same manner as steps S102 to S107 according to the first modified example (see FIGS. 5B to 5F).

In the embodiment, the first modified example, and the second modified example, the insulating film 11 corresponds to a first film and the conductive film 12 corresponds to a second film, but a combination of the first film and the second film is not particularly limited. The first film may be a conductive film and the second film may be an insulating film.

Table 4 shows candidates of a combination of the first film, the second film, and the target film 18 when the precursor of the SAM 17 is a thiol-based compound.

TABLE 4

| SAM | First Film | Second Film | Target Film |
|---|---|---|---|
| Thiol-based | SiN Film | Cu Film | AlO Film |
| | SiO Film | TaN Film | SiO Film |
| | SiOC Film | TiN Film | SiN Film |
| | SiON Film | Co Film | ZrO Film |
| | SiOCN Film | Ru Film | HfO Film |
| | SiCN Film | Au Film | |
| | Spin-On Carbon Film | | |

The candidates listed in Table 4 can be used in any combination. It is desirable that the first film be an insulating film, the second film be a conductive film, and the target film 18 formed on the surface of the first film be an insulating film.

Table 5 shows candidates of a combination of the first film, the second film, and the target film 18 when the precursor of the SAM 17 is a phosphonic acid-based compound.

TABLE 5

| SAM | First Film | Second Film | Target Film |
|---|---|---|---|
| Phosphonic | SiN Film | Cu Film | AlO Film |
| acid-based | SiO Film | TaN Film | SiO Film |
| | SiOC Film | TiN Film | SiN Film |
| | SiON Film | Co Film | ZrO Film |
| | SiOCN Film | | HfO Film |
| | SiCN Film | | |
| | Spin-On Carbon Film | | |

The candidates listed in Table 5 are used in any combination. It is desirable that the first film be an insulating film, the second film be a conductive film, and the target film 18 formed on the surface of the first film be an insulating film.

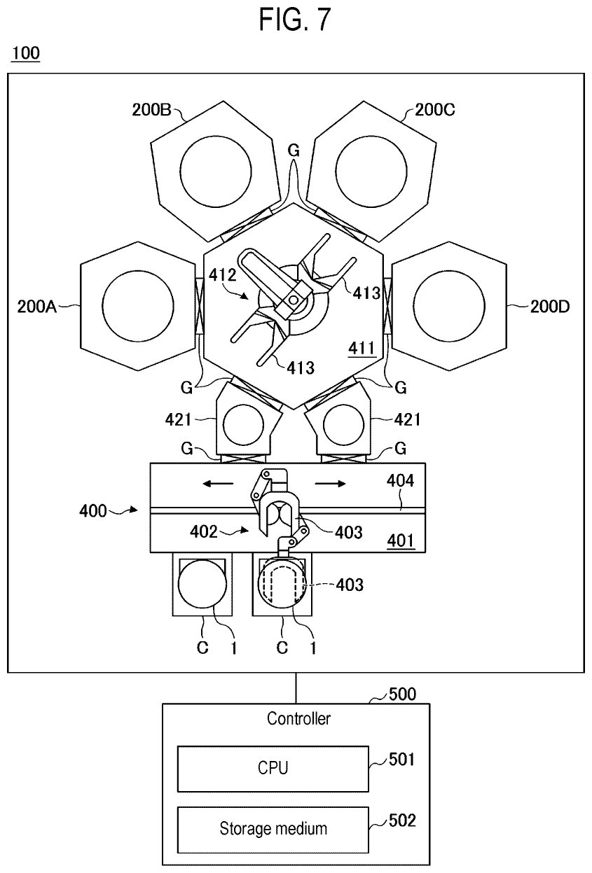

Next, a film forming apparatus 100 for performing the above film forming method will be described with reference to FIG. 7. As illustrated in FIG. 7, the film forming apparatus 100 has a first processor 200A, a second processor 200B, a third processor 200C, a fourth processor 200D, a transfer portion 400, and a controller 500. The first processor 200A performs steps S102 and S103 in FIG. 1. The second processor 200B performs step S104 in FIG. 1. The third processor 200C performs step S105 in FIG. 1. The fourth processor 200D performs steps S106 and S107 in FIG. 1. The first processor 200A, the second processor 200B, the third processor 200C, and the fourth processor 200D have the same structure. Therefore, only the first processor 200A can perform all of steps S102 to S107. The first processor 200A, the second processor 200B, the third processor 200C, and the fourth processor 200D may have different structures. The transfer portion 400 transfers the substrate 1 to the first processor 200A, the second processor 200B, the third processor 200C, and the fourth processor 200D. The controller 500 controls the first processor 200A, the second processor 200B, the third processor 200C, the fourth processor 200D, and the transfer portion 400.

The transfer portion 400 has a first transfer chamber 401 and a first transfer mechanism 402. An internal atmosphere of the first transfer chamber 401 is an atmospheric atmosphere. The first transfer mechanism 402 is provided inside the first transfer chamber 401. The first transfer mechanism 402 includes an arm 403 that holds the substrate 1 and travels along a rail 404. The rail 404 extends in an arrangement direction of a carrier C.

The transfer portion 400 also has a second transfer chamber 411 and a second transfer mechanism 412. An internal atmosphere of the second transfer chamber 411 is a vacuum atmosphere. The second transfer mechanism 412 is provided inside the second transfer chamber 411. The second transfer mechanism 412 includes an arm 413 that holds the substrate 1. The arm 413 is arranged to be movable in a vertical direction and a horizontal direction and rotatable around a vertical axis. The first processor 200A, the second processor 200B, the third processor 200C, and the fourth processor 200D is connected to the second transfer chamber 411 via different gate valves G.

Further, the transfer portion 400 has a load lock chamber 421 between the first transfer chamber 401 and the second transfer chamber 411. An internal atmosphere of the load lock chamber 421 is switched between a vacuum atmosphere and an atmospheric atmosphere by a pressure regulating mechanism which is not illustrated. Thereby, the inside of the second transfer chamber 411 can always be maintained in the vacuum atmosphere. In addition, gas can be suppressed from flowing into the second transfer chamber 411 from the first transfer chamber 401. Gate valves G are provided between the first transfer chamber 401 and the load lock chamber 421 and between the second transfer chamber 411 and the load lock chamber 421.

The controller 500 is, for example, a computer and has a central processing unit (CPU) 501 and a storage medium 502 such as a memory. The storage medium 502 stores a program for controlling various processes executed in the film forming apparatus 100. The controller 500 controls the operation of the film forming apparatus 100 by causing the CPU 501 to execute the program stored in the storage medium 502. The controller 500 controls the first processor 200A, the second processor 200B, the third processor 200C, the fourth processor 200D, and the transfer portion 400 to perform the film forming method.

Next, the operation of the film forming apparatus 100 will be described. First, the first transfer mechanism 402 takes the substrate 1 out of the carrier C, transfers the taken-out substrate 1 to the load lock chamber 421, and then exits from the load lock chamber 421. The internal atmosphere of the load lock chamber 421 is then switched from the atmospheric atmosphere to the vacuum atmosphere. Thereafter, the second transfer mechanism 412 takes the substrate 1 out of the load lock chamber 421 and transfers the taken-out substrate 1 to the first processor 200A.

Next, the first processor 200A performs steps S102 and S103. Thereafter, the second transfer mechanism 412 takes the substrate 1 out of the first processor 200A and transfers the taken-out substrate 1 to the second processor 200B. During this time, an ambient atmosphere of the substrate 1 can be maintained in the vacuum atmosphere, and therefore, oxidation of the substrate 1 can be suppressed.

Next, the second processor 200B performs step S104. Thereafter, the second transfer mechanism 412 takes the substrate 1 out of the second processor 200B and transfers the taken-out substrate 1 to the third processor 200C. During this time, the ambient atmosphere of the substrate 1 can be maintained in the vacuum atmosphere, so that the deterioration of the blocking performance of the SAM 17 can be suppressed.

Next, the third processor 200C performs step S105. Steps S105a and S105b are repeatedly performed in the same processing container. Thereafter, the second transfer mechanism 412 takes the substrate 1 out of the third processor 200C and transfers the taken-out substrate 1 to the fourth processor 200D. During this time, the ambient atmosphere of the substrate 1 can be maintained in the vacuum atmosphere.

Next, the fourth processor 200D performs steps S106 and S107. The controller 500 checks whether the first cycle C1 has been performed a set number of times (L times) (step S108). If the number of times of performing the first cycle C1 has not reached the set number of times (L times), the fourth processor 200D performs the first cycle C1 again. Steps S106 and S107 are repeatedly performed in the same processing container.

Next, the controller 500 checks whether the second cycle C2 has been performed a set number of times (M times). If the number of times of performing the second cycle C2 has not reached the set number (M times) (“NO” in step S109), the second transfer mechanism 412 takes the substrate 1 out of the fourth processor 200D and transfers the taken-out substrate 1 to the first processor 200A. Next, the controller 500 performs the second cycle C2 again.

On the other hand, if the number of times of performing the second cycle C2 has reached the set number (M times), the second transfer mechanism 412 takes the substrate 1 out of the fourth processor 200D, transfers the taken-out substrate 1 to the load lock chamber 421, and then exits from the load lock chamber 421. The internal atmosphere of the load lock chamber 421 is then switched from the vacuum atmosphere to the atmospheric atmosphere. Thereafter, the first transfer mechanism 402 takes the substrate 1 out of the load lock chamber 421 and accommodates the taken-out substrate 1 in the carrier C. Then processing of the substrate 1 is ended.

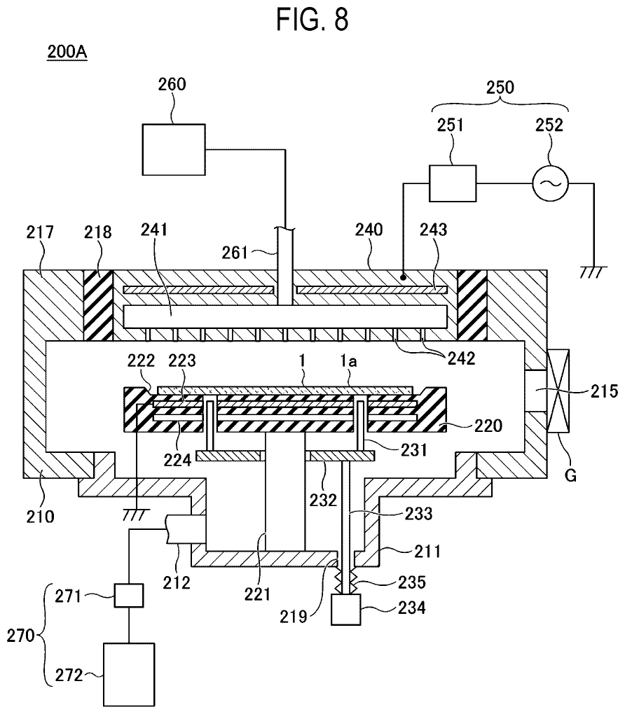

Next, the first processor 200A will be described with reference to FIG. 8. The second processor 200B, the third processor 200C, and the fourth processor 200D are configured in the same manner as the first processor 200A, and therefore, illustration and description thereof will be omitted.

The first processor 200A includes a substantially cylindrical airtight processing container 210. An exhaust chamber 211 is provided at a center portion of a bottom wall of the processing container 210. The exhaust chamber 211 has, for example, a substantially cylindrical shape that protrudes downward. An exhaust pipe 212 is connected to the exhaust chamber 211, for example, on the side of the exhaust chamber 211.

An exhaust source 272 is connected to the exhaust pipe 212 via a pressure controller 271. The pressure controller 271 includes, for example, a pressure regulating valve such as a butterfly valve. The exhaust pipe 212 is configured to depressurize the interior of the processing container 210 by the exhaust source 272. The pressure controller 271 and the exhaust source 272 constitute a gas discharge mechanism 270 that discharges gas in the processing container 210.

A transfer port 215 is provided on the side of the processing container 210. The transfer port 215 is opened and closed by a gate valve G. The substrate 1 is loaded and unloaded between the inside of the processing container 210 and the second transfer chamber 411 (see FIG. 7) through the transfer port 215.

A stage 220, which is a holder for holding the substrate 1, is provided inside the processing container 210. The stage 220 holds the substrate 1 horizontally, with the substrate surface 1a facing upward. The stage 220 is formed in a substantially circular shape in plan view and is supported by a support member 221. A substantially circular recess 222 is formed on the surface of the stage 220 to place the substrate 1 having a diameter of, for example, 300 mm. The recess 222 has an inner diameter slightly larger than the diameter of the substrate 1. The depth of the recess 222 is substantially the same as, for example, the thickness of the substrate 1. The stage 220 is made of, for example, a ceramic material such as aluminum nitride (AlN). The stage 220 may also be made of a metal material such as nickel (Ni). Instead of the recess 222, a guide ring that guides the substrate 1 may be provided at a peripheral edge of the surface of the stage 220.

In the stage 220, a grounded lower electrode 223 for example is buried. A heating mechanism 224 is embedded below the lower electrode 223. The heating mechanism 224 heats the substrate 1 placed on the stage 220 to a set temperature by being fed with power from a power supply (not illustrated) based on a control signal from the controller 500 (see FIG. 7). When the entire stage 220 is made of a metal, the entire stage 220 functions as a lower electrode, so that the lower electrode 223 does not need to be buried in the stage 220. The stage 220 is provided with a plurality of (e.g., three) lifting pins 231 for holding and raising and lowering the substrate 1 placed on the stage 220. The material of the lifting pins 231 may be, for example, ceramic such as alumina (Al₂O₃), or quartz. Lower ends of the lifting pins 231 are attached to a support plate 232. The support plate 232 is connected to a lifting mechanism 234 provided outside the processing container 210 via a lifting shaft 233.

The lifting mechanism 234 is installed, for example, below the exhaust chamber 211. A bellows 235 is provided between an opening 219 formed in a lower surface of the exhaust chamber 211, for the lifting shaft 233, and the lifting mechanism 234. The support plate 232 may be shaped to be raised and lowered without interfering with the support member 221 of the stage 220. The lifting pins 231 are configured to be elevatable between a space above an upper surface of the stage 220 and a space below a lower surface of the stage 220 by the lifting mechanism 234.

A gas supply 240 is provided in a ceiling wall 217 of the processing container 210 via an insulating member 218. The gas supply 240 constitutes an upper electrode and faces the lower electrode 223. A radio-frequency power supply 252 is connected to the gas supply 240 via a matcher 251. By supplying a radio-frequency power of 400 kHz to 40 MHz from the radio-frequency power supply 252 to the upper electrode (gas supply 240), a radio-frequency electric field is generated between the upper electrode (gas supply 240) and the lower electrode 223 to generate capacitively coupled plasma. A plasma generator 250 that generates plasma includes the matcher 251 and the radio-frequency power supply 252. The plasma generator 250 may be a plasma generator that generates other plasma, such as inductively coupled plasma, without being limited to the capacitively coupled plasma. In a process in which plasma is not generated, the gas supply 240 does not need to constitute the upper electrode, and the lower electrode 223 is also unnecessary.

The gas supply 240 includes a hollow gas supply chamber 241. A plurality of holes 242 for dispersing and supplying a process gas into the processing container 210 is arranged, for example, uniformly, on a lower surface of the gas supply chamber 241. In the gas supply 240, a heating mechanism 243 is buried, for example, above the gas supply chamber 241. The heating mechanism 243 is heated to a set temperature by being fed with power from the power supply (not illustrated) based on the control signal from the controller 500.

A gas supply mechanism 260 is connected to the gas supply chamber 241 via a gas supply path 261. The gas supply mechanism 260 supplies gas used in at least one of steps S102 to S107 in FIG. 1 to the gas supply chamber 241 via the gas supply path 261. Although not illustrated, the gas supply mechanism 260 includes an individual pipe, an on-off valve provided in the middle of the individual pipe, and a flow rate controller provided in the middle of the individual pipe, for each type of gas. When the individual pipe is opened by the on-off valve, gas is supplied from a supply source to the gas supply path 261. The amount of supply of the gas is controlled by the flow rate controller. On the other hand, when the individual pipe is closed by the on-off valve, the supply of the gas from the supply source to the gas supply path 261 is stopped.

While the embodiments of the film forming method and the film forming apparatus according to the present disclosure have been described, the present disclosure is not limited to the above embodiments. Various changes, modifications, substitutions, additions, deletions, and combinations are possible within the scope of the claims. These naturally fall within the technical scope of the present disclosure.

This application claims priority based on Japanese Patent Application No. 2022-049569 filed on Mar. 25, 2022, and the disclosure of Japanese Patent Application No. 2022-049569 is incorporated into this application in its entirety.

### EXPLANATION OF REFERENCE NUMERALS

1: substrate, 1a: substrate surface, 11: insulating film (first film), 12: conductive film (second film), 17: SAM (self-assembled monolayer), 18: target film, 18a: partial portion, 18b: remaining portion

1. A film forming method, comprising:
(A) preparing a substrate having a first film and a second film made of a material different from a material of the first film in different regions of a surface of the substrate;
(B) selectively forming a self-assembled monolayer on a surface of the second film with respect to a surface of the first film using an organic compound not containing fluorine;
(C) after (B), forming a target film on the surface of the first film while inhibiting the target film from being formed on the surface of the second film using the self-assembled monolayer;
(D) after (C), fluorinating a partial portion of the target film faster than a remaining portion of the target film using a fluorine-containing gas; and
(E) after (D), etching the partial portion of the target film faster than the remaining portion of the target film using an etching gas,
wherein the partial portion of the target film is deposited on the self-assembled monolayer.

2. The film forming method of claim 1, wherein the organic compound used in (B) includes a hydrocarbon group and a functional group provided at one end of the hydrocarbon group, and
wherein the functional group is chemically adsorbed to the surface of the second film.

3. The film forming method of claim 2, wherein the fluorine-containing gas used in (D) includes at least one selected from among HF gas, F₂ gas, and ClF₃ gas.

4. The film forming method of claim 1, wherein the etching gas used in (E) includes at least one selected from among H₂ gas, NH₃ gas, N₂ gas, and Ar gas and is supplied to the surface of the substrate in a plasma state.

5. The film forming method of claim 1, wherein the etching gas used in (E) includes at least one selected from among trimethylaluminum (TMA) gas, dimethylacetamide (DMAC) gas, tin (II) acetylacetonate gas, Cl₂ gas, BCl₃ gas, and TiC₄ gas.

6. The film forming method of claim 1, wherein a first cycle including (D) and (E) is repeatedly performed multiple times.

7. The film forming method of claim 1, wherein a second cycle including (B), (C), (D), and (E) is repeatedly performed multiple times.

8. The film forming method of claim 7, wherein, in the second cycle, a first cycle including (D) and (E) is repeatedly performed multiple times after (B) and (C) are performed.

9. The film forming method of claim 1, wherein one of the first film and the second film is an insulating film and the other one thereof is a conductive film.

10. The film forming method of claim 9, wherein the conductive film is a Cu film, a Co film, a Ru film, a W film, or a Mo film.

11. A film forming apparatus, comprising:
a processing container;
a holder configured to hold the substrate inside the processing container;
a gas supply mechanism configured to supply gas to an interior of the processing container;
a gas discharge mechanism configured to discharge gas from the interior of the processing container;
a transfer mechanism configured to load or unload the substrate into or from the processing container; and
a controller configured to control the gas supply mechanism, the gas discharge mechanism, and the transfer mechanism to perform the film forming method of claim 1.

12. The film forming method of claim 1, wherein the fluorine-containing gas used in (D) includes at least one selected from among HF gas, F₂ gas, and ClF₃ gas.
